(19) United States
(12) Patent Application Publication
(10) Pub. No.: US 2009/0085056 A1
(43) Pub. Date: Apr. 2, 2009

(54) OPTICAL SEMICONDUCTOR DEVICE AND METHOD FOR FABRICATING THE SAME

(75) Inventor: Chaiyasit KUMTORNKITTIKUL, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/183,435

(22) Filed: Jul. 31, 2008

(30) Foreign Application Priority Data
Aug. 2, 2007 (JP) 2007-201942

(51) Int. Cl. H01L 33/00; H01L 21/20

(52) U.S. Cl. 257/103; 438/46; 257/E33.025; 257/E21.09

(57) ABSTRACT

According to an aspect of the present invention, there is provided an optical semiconductor device, comprising, a first AlN clad-layer, a first nitride semiconductor guide-layer formed on the first AlN clad-layer, refractive index of the first nitride semiconductor guide-layer being larger than refractive index of the first AlN clad-layer, a nitride semiconductor core-layer formed on the first nitride semiconductor guide-layer, refractive index of the nitride semiconductor core-layer being larger than refractive index of the first AlN clad-layer and smaller than refractive index of the first nitride semiconductor guide-layer, a second nitride semiconductor guide-layer formed on the nitride semiconductor core-layer, refractive index of the second nitride semiconductor guide-layer being larger than refractive index of the nitride semiconductor core-layer, a second AlN clad-layer formed on the second nitride semiconductor guide-layer.

### CROSS REFERENCE TO RELATED APPLICATION

This application is based upon and claims the benefit of priority from the prior Japanese Application (No. 2007-201942, filed Aug. 2, 2007), the entire contents of which are incorporated herein by reference.

### FIELD OF THE INVENTION

The present invention relates to an optical semiconductor and a method for fabricating the optical semiconductor, and in particular, to an optical nitride semiconductor and a method for fabricating the optical nitride semiconductor.

### DESCRIPTION OF THE BACKGROUND

Recently, a high-capacity optical switching system and a high-capacity optical information processing system have been demanded accompanying with development of a long-haul and high-capacity optical communication system. In the systems, optical elements, for example, optical switch and an optical arithmetic logic element with ultra-high speed operation, respectively, are necessary.

An optical waveguide formed with nitride semiconductors is well-known as an optical switch. The optical wave guide includes a quantum-well structure with a core-layer being sandwiched by clad-layers. For example, Chaiyasit KUMTORNKITTIKUL et al. discloses the above-mentioned technology in “AlN Waveguide with GaN/AlN Quantum Wells for All-Optical Switching Utilizing Intersubband Transition” (Japanese Journal of Applied Physics Vol. 46, No 15, 2007, pp. L352-L355).

An optical waveguide disclosed in the above-mentioned paper is constituted with a lower AlN clad-layer on a sapphire substrate, a GaN quantum-well layer on the lower AlN clad-layer, a GaN/AlN MQW (multi quantum-well) core-layer having an AlN barrier-layer, and an upper AlN clad-layer on the GaN/AlN MQW core-layer.

However, in the optical waveguide disclosed in the above-mentioned paper, a difference between refractive index of the GaN/AlN MQW core-layer and refractive index of the AlN clad-layer is not fully satisfied for obtaining desirable optical confinement effect.

Therefore, an optical intensity in the GaN/AlN MQW core-layer is weak. Accordingly, optical absorption efficiency and optical amplification efficiency of the GaN/AlN MQW core-layer are not substantially filled.

### SUMMARY OF INVENTION

According to an aspect of the invention, there is provided an optical semiconductor device, comprising, a first AlN clad-layer, a first nitride semiconductor guide-layer formed on the first AlN clad-layer, refractive index of the first nitride semiconductor guide-layer being larger than refractive index of the first AlN clad-layer, a nitride semiconductor core-layer formed on the first nitride semiconductor guide-layer, refractive index of the nitride semiconductor core-layer being larger than refractive index of the first AlN clad-layer and smaller than refractive index of the first nitride semiconductor guide-layer, a second nitride semiconductor guide-layer formed on the nitride semiconductor core-layer, refractive index of the second nitride semiconductor guide-layer being larger than refractive index of the nitride semiconductor core-layer, a second AlN clad-layer formed on the second nitride semiconductor guide-layer.

Further, according to another aspect of the invention, there is provided a method for fabricating an optical semiconductor device, comprising, forming a first AlN clad-layer over a substrate, forming a first nitride semiconductor guide-layer on the first AlN clad-layer, refractive index of the first nitride semiconductor guide-layer being larger than refractive index of the first AlN clad-layer, forming a nitride semiconductor core-layer on the first nitride semiconductor guide-layer, refractive index of the nitride semiconductor core-layer being larger than refractive index of the first AlN clad-layer being smaller than refractive index of the first nitride semiconductor guide-layer, forming a second nitride semiconductor guide-layer on the nitride semiconductor core-layer, refractive index of the second nitride semiconductor guide-layer being larger than refractive index of the nitride semiconductor core-layer, forming a second AlN clad-layer on the second nitride semiconductor guide-layer.

### BRIEF DESCRIPTION OF THE DRAWINGS

FIG. 1A is a cross-sectional schematic view showing an optical semiconductor device and FIG. 1B is a refractive index distribution showing characteristic of the optical semiconductor device according to a first embodiment of the present invention;

FIG. 2A is a schematic diagram showing optical confinement effect of the optical semiconductor device according to the first embodiment of the present invention and FIG. 2B is a schematic diagram showing optical confinement effect of the optical semiconductor device according to a conventional case;

FIGS. 3A-3C are cross-sectional schematic views showing processing steps of the optical semiconductor device in order according to the first embodiment of the present invention;

FIGS. 4A-4B are cross-sectional schematic views showing the processing steps of the optical semiconductor device in order according to the first embodiment of the present invention;

FIG. 5 is a cross-sectional schematic view showing the processing steps of the optical semiconductor device in order according to the first embodiment of the present invention;

FIG. 6 is a cross-sectional schematic view showing an optical semiconductor device according to a second embodiment of the present invention;

FIG. 7 is a cross-sectional schematic view showing an optical semiconductor device according to a third embodiment of the present invention;

FIG. 8 is a cross-sectional schematic view showing an optical semiconductor device according to a fourth embodiment of the present invention;

FIG. 9 is a schematic diagram showing a relationship between a thickness of a core portion and an optical propagating mode according to the fourth embodiment of the present invention;

FIG. 10 is a cross-sectional schematic view showing an optical semiconductor device according to a fifth embodiment of the present invention;

FIG. 11 is a cross-sectional schematic view showing an optical semiconductor device according to a sixth embodiment of the present invention;

FIG. 12 is a cross-sectional schematic view showing an optical semiconductor device according to a seventh embodiment of the present invention;

FIG. 13A is a cross-sectional schematic view showing an optical semiconductor device and FIG. 13B is a photo-emission spectrum showing characteristic of the optical semiconductor device according to an eighth embodiment of the present invention;

FIG. 14A is a cross-sectional schematic view showing an optical semiconductor device and FIG. 14B is a photo-absorption spectrum showing characteristic of the optical semiconductor device according to a ninth embodiment of the present invention;

FIG. 15 is a cross-sectional schematic view showing an optical semiconductor device according to a tenth embodiment of the present invention.

### DETAILED DESCRIPTION OF THE INVENTION

Embodiments of the present invention will be described below in detail with reference to the drawings mentioned above.

It is to be noted that the same or similar reference numerals are applied to the same or similar parts and elements throughout the drawings, and the description of the same or similar parts and elements will be omitted or simplified.

### First Embodiment

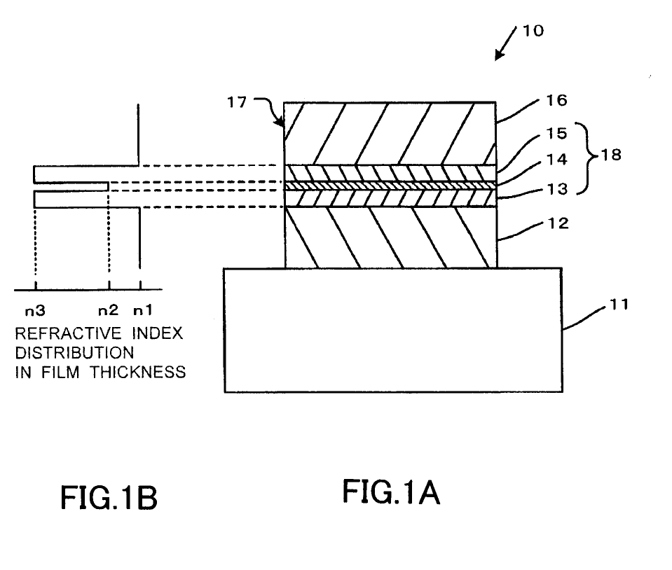

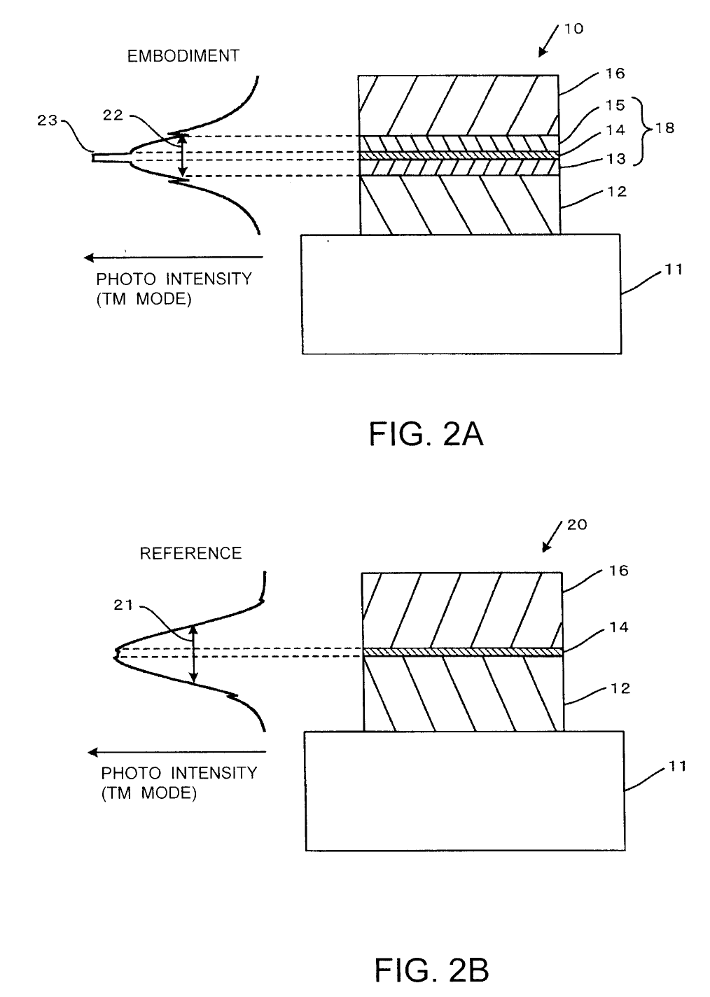

An optical semiconductor device according to a first embodiment of the present invention is explained by using FIG. 1 and FIG. 2.

FIG. 1A is a cross-sectional schematic view showing the optical semiconductor device and FIG. 1B is a refractive index distribution showing characteristic of the optical semiconductor device according to the first embodiment of the present invention. FIG. 2A is a schematic diagram showing optical confinement effect according to the first embodiment of the present invention and FIG. 2B is a schematic diagram showing optical confinement effect of the optical semiconductor device according to a conventional case.

In this embodiment, the optical semiconductor device includes a ridge-type optical wave guide and an optical switch absorbing infrared of a 1.3-1.55 μm band by intersubband transition in a quantum well, as an example.

As shown in FIG. 1A, an optical semiconductor device 10 in this embodiment includes a substrate 11, for example, a sapphire substrate, a first aluminum nitride (AlN) clad-layer 12, a first nitride semiconductor guide-layer 13, a nitride semiconductor core-layer 14, a second nitride semiconductor guide-layer 15 and a second AlN clad-layer 16. The first AlN clad-layer 12 is formed over the substrate 11 via a buffer layer (not illustrated). The first nitride semiconductor guide-layer 13 is formed on the first AlN clad-layer 12 and refractive index of the first nitride semiconductor guide-layer 13 is larger than that of the first AlN clad-layer 12. The nitride semiconductor core-layer 14 is formed on the first nitride semiconductor guide-layer 13 and refractive index of the nitride semiconductor core-layer 14 is larger than that of the first AlN clad-layer 12 and smaller than that of the first nitride semiconductor guide-layer 13. The second nitride semiconductor guide-layer 15 is formed on the nitride semiconductor core-layer 14 and refractive index of the second nitride semiconductor guide-layer 15 is larger than that of the nitride semiconductor core-layer 14. The second AlN clad-layer 16 is formed on the second nitride semiconductor guide-layer 15.

A ridge-type optical waveguide 17 is constituted with the layers from the first AlN clad-layer 12 to the second AlN clad-layer 16.

For example, the first nitride semiconductor guide-layer 13 and the second nitride semiconductor guide-layer 15 are constituted with indium nitride (InN) having the highest refractive index in a group of nitride semiconductors. For example, the nitride semiconductor core-layer 14 is constituted with a multiple quantum well (GaN/AlN MQW) having a gallium nitride (GaN) quantum well layer and an aluminum-nitride (AlN) barrier-layer.

As shown in FIG. 1B, when refractive index of the first AlN clad-layer 12 and the second AlN clad-layer 16 is set as n1, refractive index of the GaN/AlN MQW core-layer 14 is set as n2, refractive index of the first InN guide-layer 13 and the second InN guide-layer 15 is set as n3, a relation of n1<n2<n3 is established. Refractive indexes n1, n2 and n3 are estimated to be approximately 1.95, 2.1 and 2.6, respectively, for example at a wavelength of 1.55 μm.

From the above conditions, the optical semiconductor 10 has a concave-type refractive index distribution and a total refractive index of the core portion 18 becomes larger. The total refractive index of the core portion 18 is a weighted average value between the GaN/AlN MQW core-layer 14, the first InN guide-layer 13 and the second InN guide-layer 15. Accordingly, a refractive index difference between the core portion 18 and the two AlN clad-layers, the first AlN clad-layer 12 and the second AlN clad-layer 16, is increased as compared to a case without the first InN guide-layer 13 and the second InN guide-layer 15.

As a result, an optical strength of the core portion 18 substantially rises up as compared to the other layers to allow obtaining higher optical confinement effect.

FIG. 2A is a schematic diagram showing optical confinement effect by a simulation approach as compared to the conventional case as shown in FIG. 2B.

In this embodiment, the conventional case means an optical semiconductor being constituted without the first InN guide-layer 13 and the second InN guide-layer 15 and constituted with GaN/AlN MQW core-layer 14 directly sandwiched by the first AlN clad-layer 12 and the second AlN clad-layer 16.

First, the conventional case is explained.

As shown in FIG. 2B, (n2−n1) being a difference between refractive index n2 of the GaN/AlN MQW core-layer 14 and refractive index n1 of the two AlN clad-layers, the first AlN clad-layer 12 and the second AlN clad-layer 16, is small in the optical semiconductor 20 of the conventional case. Accordingly, light in the GaN/AlN MQW core-layer 14 leaks to the first AlN clad-layer 12 and the second AlN clad-layer 16 so that a half width 21 of an optical intensity (TM-mode) becomes broad.

As a result, the optical intensity of the GaN/AlN MQW core-layer 14 becomes weak so that high optical confinement effect is not obtained.

On the other hand, as shown in FIG. 2A, (n3−n1) being a difference between refractive index n3 of the InN guide-layers, the first InN guide-layer 13 and the second InN guide-layer 15, and refractive index n1 of AlN clad-layers, the first AlN clad-layer 12 and the second AlN clad-layer 16, is large in the optical semiconductor 10 of this embodiment. Accordingly, the light leakage to the first AlN clad-layer 12 and the second AlN clad-layer 16 is decreased so that a half width 22 of the optical intensity becomes sharp.

As the light is concentrated in the GaN/AlN MQW core-layer 14, the optical strength distribution (TM-mode) with a steeple portion 23 is obtained. The reason is mentioned below.

When electromagnetic wave (light) propagates from one material into the other material with different refractive index to the one material, a parallel component to the boundary plane satisfies the boundary condition which the intensity is the same in the both materials. In this case, the component is electric field in TE mode and magnetic field in TM-mode.

When the propagation mode is TM-mode, the parallel component to the boundary plane is magnetic field. Therefore, the light is concentrated to equalize the intensity at the boundary plane. As the component of electric field is also amplified by the above-mentioned case, the optical intensity distribution with the steeple portion 23 is obtained. In addition, when the propagation mode is TE-mode, the parallel component to the boundary plane is electric field so as to obtain a smooth wave.

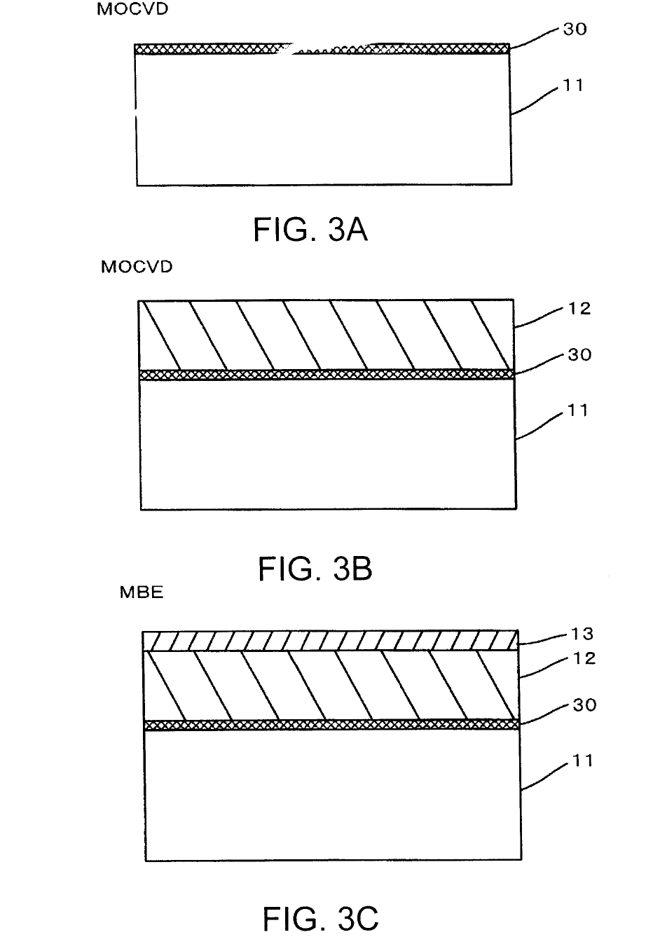

Next, a method for fabricating the optical semiconductor device 10 is explained by using FIG. 3-FIG. 5. The optical semiconductor device 10 is fabricated by a combination of well-known MOCVD (Metal Organic Chemical vapor deposition) and well-known MBE (Molecular Beam Epitaxy). The reason for combining with MOCVD and MBE is mentioned below. As vapor pressure of In is high, growth of an InN film with less crystal defect is difficult by MOCVD.

First, the first AlN clad-layer 12 is formed over the substrate 11 by MOCVD. Next, the first InN guide-layer 13, the nitride semiconductor core-layer 14, the second nitride semiconductor guide-layer 15 and the second AlN clad-layer 16 is successively stacked in layer over the first AlN clad-layer 12 by MBE.

As shown in FIG. 3A, the AlN buffer layer 30 having a thickness of approximately 20 nm is formed on the substrate 11 by MOCVD, for example, at a pressure of 6 kPa and a growth temperature of 800° C. to relief lattice mismatch between sapphire and AlN.

As shown in FIG. 3B, the first AlN clad-layer 12 having a thickness of approximately 1 μm is formed over the substrate 11 via an AlN buffer layer 30, for example, at a growth temperature being up to 1250° C. In the processing step, lattice mismatch between sapphire and AlN is relieved to obtain the first AlN clad-layer 12 with less crystal defects.

As shown in FIG. 3C, the substrate 11 is carried out from a MOCVD machine, subsequently inserted in an MBE machine. The first InN guide-layer 13 having a thickness of approximately 50 nm is formed on the first AlN clad-layer 12 by MBE, for example, at a pressure of 1.3×⁻⁹ kPa and at a growth temperature of 600° C.

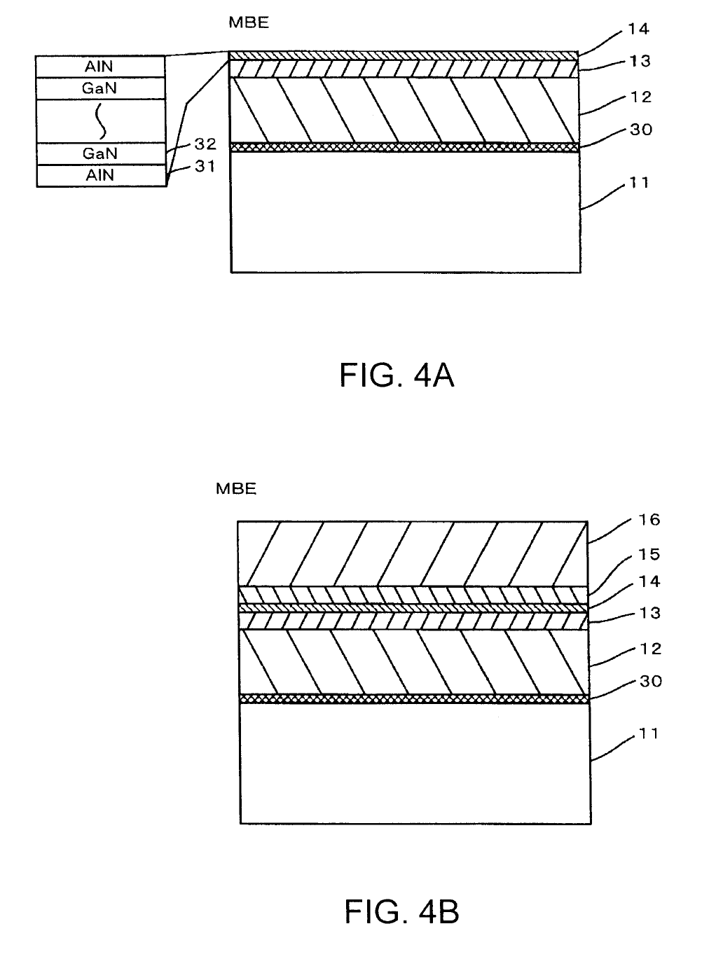

As shown in FIG. 4A, for example, ten pairs of a AlN barrier-layer 31 having a thickness of approximately 2 nm and a GaN quantum well layer 32 having a thickness of approximately 2 nm are alternatively formed on the first InN guide-layer 13 with irradiating In-beams for suppressing pyrolysis of the first InN guide-layer 13 by lowering a growth temperature down at 400° C.

As shown in FIG. 4B, the second InN guide-layer 15 having a thickness of approximately 50 nm is formed on the GaN/AlN MQW core-layer 14, for example, at a growth temperature of 600° C.

Next, the second AlN clad-layer 16 having a thickness of approximately 1 μm is formed on the second InN guide-layer 15 with irradiating In-beams for suppressing pyrolysis of the second InN guide-layer 15, for example, by rising a growth temperature up at 800° C.

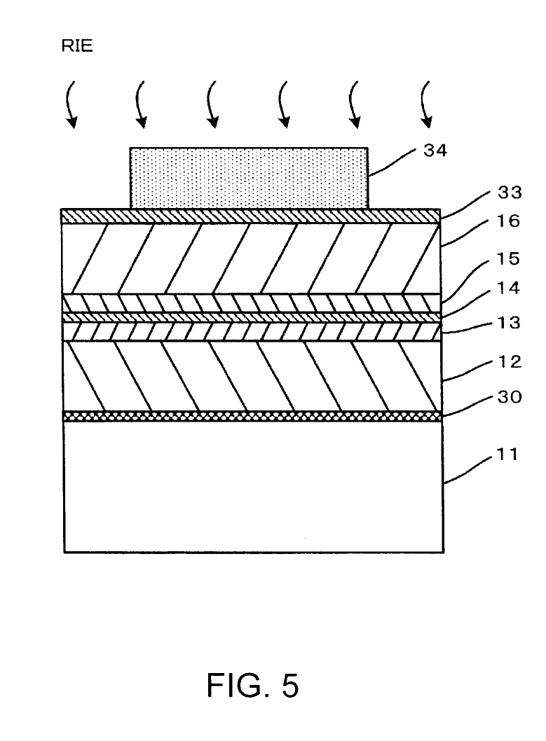

As shown in FIG. 5, a silicon dioxide film having a thickness of approximately 0.5 μm as a protective film 33 is formed on the second AlN clad-layer 16 for suppressing Al oxidation. A resist film 34 having patterns corresponding to the ridge-type optical waveguide 17 is formed on the protective film 33 by photo-lithography technique. The stacked layers from the protective film 33 to the AlN buffer layer 30 are anisotropically etched in order by RIE (Reactive Ion Etching) technique using the resist film 34 as a mask.

The optical semiconductor device 10 having the ridge-type optical waveguide 17 as shown in FIG. 1 is obtained by the above-mentioned processing steps.

As MBE technique has high contorollability on a thin film thickness, an operation wavelength of the GaN/AlN MQW core-layer 14 is easily controlled to be well suited as fabricating an optical switch utilizing intersubband transition absorption.

As mentioned above, the optical semiconductor device 10 in this embodiment includes the first InN guide-layer 13 and the second InN guide-layer 15 having the highest refractive index, respectively, between the GaN/AlN MQW core-layer 14 and the two AlN clad-layers, the first AlN clad-layer 12 and the second AlN clad-layer 16, in the nitride semiconductors.

As a result, the difference between the refractive index of the core portion 18 constituted with the GaN/AlN MQW core-layer 14, the first InN guide-layer 13 and the second InN guide-layer 15 and the refractive index of the two AlN clad-layers 12 and 16 becomes larger to considerably enhance the optical intensity of the core portion 18.

Therefore, the optical semiconductor device 10 having high optical confinement effect is provided.

Here, it is explained as an example that the substrate 11 is the sapphire substrate with larger lattice mismatch ratio. However, a SiC substrate or a GaN substrates with smaller lattice mismatch ratio, respectively, can be suited.

SiC and GaN are also superior to sapphire from view points of larger thermal conductivity and higher conductivity.

It is explained as an example that the first InN guide-layer 13 is directly formed on the first AlN clad-layer 12, however, lattice constant between AlN and InN is different. Therefore, the first InN guide-layer 13 may be formed via AlN as a low temperature buffer layer, for example, to relief the lattice mismatch for obtaining the layer with less crystal defects. The second AlN clad-layer 16 on the second InN guide-layer 15 can be similarly grown.

It is explained as an example that impurities is not doped in the stacked layers from the first AlN clad-layer 12 to the second AlN clad-layer 16, however, the impurities may be doped depending on requirement.

### Second Embodiment

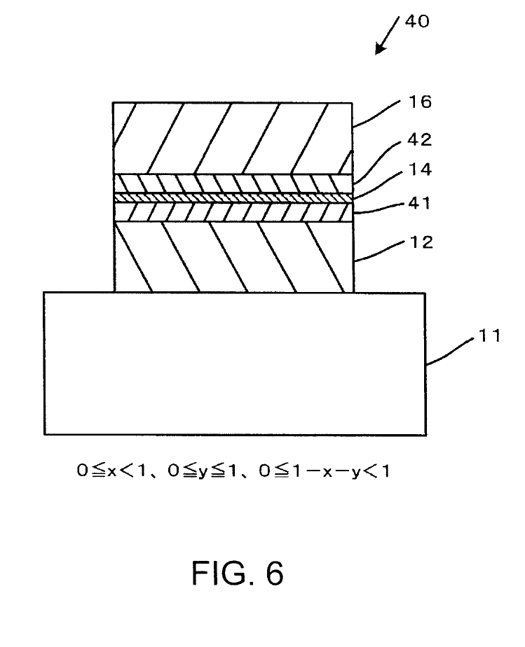

FIG. 6 is a cross-sectional schematic view showing an optical semiconductor device according to a second embodiment of the present invention. It is to be noted that the same reference numerals in FIG. 1 are attached to the same parts and elements in FIG. 6 as those in FIG. 1. Further, the description of the same parts and elements will be omitted.

This embodiment is different to the first embodiment in the first guide-layer and the second guide-layer being constituted with InₓGa_{y}Al_{(1-x-y)}N.

As shown in FIG. 6, an optical semiconductor device 40 in this embodiment includes a first InₓGa_{y}Al_{(1-x-y)}N guide-layer 41, hereafter called the first guide-layer 41, and a second InₓGa_{y}Al_{(1-x-y)}N guide-layer 42, hereafter called the second guide-layer 42, between the GaN/AlN MQW core-layer 14 and the two AlN clad-layers, the first AlN clad-layer 12 and the second AlN clad-layer 16.

A relation between compositions x,y is 0≦x≦1 and 0≦y≦1, and is satisfied with 0≦1−x−y<1. Further, refractive index of the first guide-layer 41 and the second guide-layer 42 is selected in a range being higher than refractive index of the GaN/AlN MQW core-layer 14. However, a combination between x=1, y=0 (InN) and x=y=0 (AlN) are omitted.

As InGaAlN has a smaller lattice mismatch ratio than that of InN to AlN and GaN, GaN/AlN MQW core-layer 14 with less crystal defects can be formed. However, InGaAlN has smaller refractive index than that of InN, therefore, optical confinement effect is lowered due to the refractive index difference.

Accordingly, in consideration with the crystalline quality and optical confinement effect, composition x can be selected in the range from nearly 0.5 to 1 and composition y can be selected in the range from nearly 0.5 to 0.

As mentioned above, the optical semiconductor device 40 in this embodiment includes the first guide-layers 41 and the second guide-layers 42 being constituted with InₓGa_{y}Al_{(1-x-y)}N and the GaN/AlN MQW core-layer 14 with less crystal defect is obtained. As a result, the optical semiconductor 40 has an advantage in improvement of reliability.

It is explained as an example that composition x of the first guide-layer 41 and composition y of the second guide-layer 42 are the same composition, however, the composition may be different each other.

### Third Embodiment

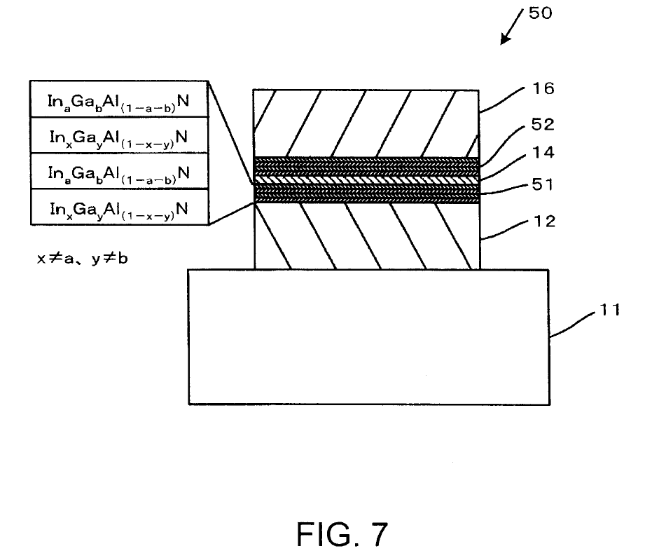

FIG. 7 is a cross-sectional schematic view showing an optical semiconductor device according to a third embodiment of the present invention. It is to be noted that the same reference numerals in FIG. 1 are attached to the same parts and elements in FIG. 7 as those in FIG. 1. Further, the description of the same parts and elements will be omitted and the different parts and elements will be explained.

This embodiment is different to the first embodiment in the first guide-layer and the second guide-layer being constituted with InₓGa_{y}Al_{(1-x-y)}N stacked-layers, each of the layers having a different composition each other.

As shown in FIG. 7, an optical semiconductor device 50 in this embodiment includes, for example, the first guide-layer 51 and the second guide-layer 52 respectively having two pairs of InₓGa_{y}Al_{(1-x-y)}N and InₐGa_{b}Al_{(1-a-b)}N stacked in layer between the GaN/AlN MQW core-layer 14 and the two AlN clad-layers, the first AlN clad-layer 12 and the second AlN clad-layer 16.

Relation between composition (x,y) and composition (a,b) are x≠a, y≠b. Further, refractive index of the first guide-layer 51 and the second guide-layer 52 is selected in a range being higher than refractive index of the GaN/AlN MQW core-layer 14. However, a condition of x=y=0 is omitted.

When x=1 and y=0 are selected as the compositions x,y of InₓGa_{y}Al_{(1-x-y)}N, for example, InₓGa_{y}Al_{(1-x-y)}N is InN. When a=0.5 and b=0.5 are selected as the compositions a,b of InₐGa_{b}Al_{(1-a-b)}N, for example, InₐGa_{b}Al_{(1-a-b)}N is In_{0.5}Ga_{0.5}N, hereafter called InGaN.

As the stacked layers with the InN layer and the InGaN layer are set as a super lattice structure, each of the layers having a film thickness below critical thickness in which crystal defects are not generated by lattice distortion, so that propagation of crystal defects from the substrate 11 can be hindered.

As a result, crystal defects in the first guide-layer 51 and the second guide-layer 52 are decreased so that the film thicknesses of the first guide-layer 51 and the second guide-layer 52 can be thicker than a film thickness of a single layer.

By the film thicknesses of the first guide-layer 51 and the second guide-layer 52 are thicker, leakage light from the first guide-layer 51 and the second guide-layer 52 to the first AlN clad-layer 12 and the second AlN clad-layer 16 is decreased so that more light can be confined in the GaN/AlN MQW core-layer 14.

As mentioned above, the optical semiconductor device 50 in this embodiment includes the first guide-layer 51 and the second guide-layer 52 having the supper lattice structure of InN and InGaN. As a result, crystal defects in the first guide-layer 51 and the second guide-layer 52 are decreased so that the film thicknesses of the first guide-layer 51 and the second guide-layer 52 can be thickened as compared to a single layer case. Accordingly, the optical semiconductor 50 has an advantage obtaining higher optical confinement effect.

It is explained as an example that two pairs of InN/InGaN is used as the first guide-layer 51 and the second guide-layer 52, however, a number of the stacked layers are not restricted.

The stacked layers may be constituted with InGaN and Ga_{0.5}Al_{0.5}N called GaAlN hereafter. As crystal defects in the stacked layers of InGaN and GaAlN are decreased as compared to crystal defects in the stacked layers of InN and InGaN, the stacked layers of InGaN and GaAlN has an advantage to thicken the film thickness.

Further, it is explained as an example that a composition (x,y) of the first guide-layer 51 and a composition (a,b) of the second guide-layer 52 are the same, however, the composition (x,y) may be differ to the composition (a,b).

### Fourth Embodiment

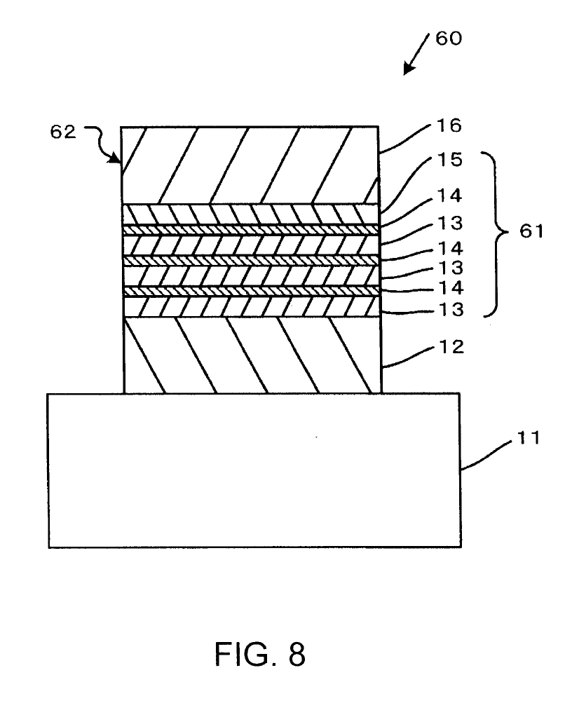

FIG. 8 is a cross-sectional schematic view showing an optical semiconductor device according to a fourth embodiment of the present invention. It is to be noted that the same reference numerals in FIG. 1 are attached to the same parts and elements in FIG. 8 as those in FIG. 1. Further, the description of the same parts and elements will be omitted and the different parts and elements will be explained.

This embodiment is different to the first embodiment in the InN guide-layers and the GaN/AlN MQW core-layer being alternatively stacked in layer.

As shown in FIG. 8, an optical semiconductor device 60 in this embodiment includes three pairs of the first InN guide-layer 13 and the GaN/AlN MQW core-layer 14 are alternatively stacked in layer. Each of the first InN guide-layers 13 is inserted between the two GaN/AlN MQW core-layers 14 so that lattice distortion in the GaN/AlN MQW core-layer 14 can be relieved even if a total film thickness of the GaN/AlN MQW core-layer 14 is increased.

According to the method described above, a core portion 61 with large total thickness is obtained from the first InN guide-layer 13 on the first AlN clad-layer to the second InN guide-layer 15.

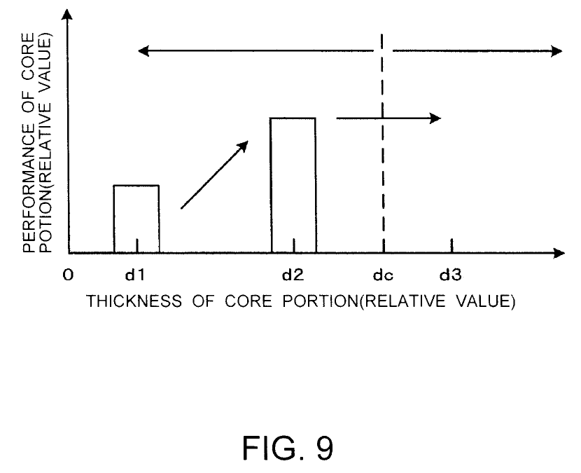

FIG. 9 is a schematic diagram showing a relationship between a total thickness of the core portion 61 and an optical propagation-mode of an optical waveguide 62.

As shown in FIG. 9, the propagation-mode of the optical waveguide 62 changes from single-mode to multi-mode at critical film thickness dc as a boundary.

When a thickness d of the core portion 61 is enlarged from a thinner thickness d1 to a thicker thickness d2 to approach the critical film thickness dc in single-mode of the optical waveguide 62, the core portion 61 absorbs more light and can operate less consumption power.

As mentioned above, the optical semiconductor device 60 in this embodiment includes the core portion 61 alternatively stacked the first InN guide-layer 13 and the GaN/AlN MQW core-layer 14 in order. As a result, the total film thickness of the core portion 61 can be thickened to improve performances of the core portion 61 such as optical absorption and consumption power.

It is explained as an example that the thickness d of the core portion 61 is below the critical film thickness dc at which the propagation-mode of the optical waveguide changes to single-mode. However, the optical semiconductor device 60 can be operated in multi-mode as a film thickness d3 being thicker than the critical film thickness dc.

### Fifth Embodiment

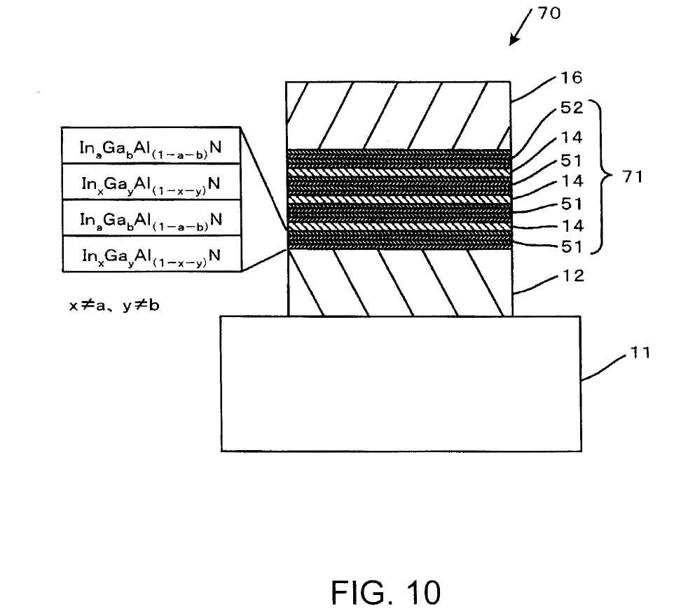

FIG. 10 is a cross-sectional schematic view showing an optical semiconductor device according to a fifth embodiment of the present invention. It is to be noted that the same reference numerals in FIG. 1 are attached to the same parts and elements in FIG. 10 as those in FIG. 1. Further, the description of the same parts and elements will be omitted and the different parts and elements will be explained.

This embodiment is different to the first embodiment in the guide-layer having InGaAlN-system multi layer film and the GaN/AlN MQW core-layer being alternatively stacked in layer.

As shown in FIG. 10, an optical semiconductor device 70 in this embodiment includes three pairs of the first guide-layer 51 and the GaN/AlN MQW core-layer 14 alternatively stacked in layer. As the guide-layer is set as the InGaAlN-system multi layers, crystal defects in the guide-layer are decreased so that a core portion 71 having thicker total film thickness can be formed.

As mentioned above, the optical semiconductor device 70 in this embodiment includes the core portion 71, alternatively stacked the first guide-layer 51 and the GaN/AlN MQW core-layer 14 in order. As a result, the optical semiconductor 70 has an advantage to form the core portion 71 having a thicker total film thickness.

It is explained as an example that the guide-layer is the first guide-layer 51 stacked InN/InGaN in order. However, the guide-layer stacked InGaN/GaAlN in order.

### Sixth Embodiment

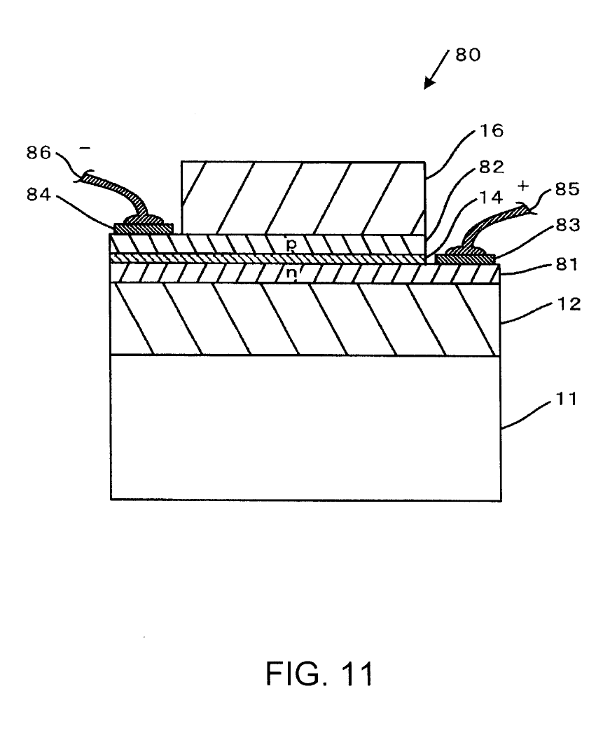

FIG. 11 is a cross-sectional schematic view showing an optical semiconductor device according to a sixth embodiment of the present invention. It is to be noted that the same reference numerals in FIG. 1 are attached to the same parts and elements in FIG. 11 as those in FIG. 1. Further, the description of the same parts and elements will be omitted and the different parts and elements will be explained.

This embodiment is different to the first embodiment in forming an electrode turning on electrical current between the guide-layers, the first guide-layer and the second guide-layer, and the GaN/AlN MQW core-layer.

As shown in FIG. 11, an optical semiconductor device 80 in this embodiment includes an n-type first InN guide-layer 81 doped with silicon (Si), for example, and a p-type second InN guide-layer 82 doped with magnesium (Mg), for example.

One side of the second AlN clad-layer 16, the p-type second InN guide-layer 82 and the GaN/AlN MQW core-layer 14 is removed and a portion of the n-type first InN guide-layer 81 is exposed. For example, Ti/Al as an electrode (first electrode) 83 of an n-type side is formed on the exposed portion of the n-type first InN guide-layer 81.

Similarly, the other side of the second AlN clad-layer 16 is removed, a portion of the p-type second InN guide-layer 82 is exposed. For example, Ti/Au as an electrode (second electrode) 84 of an p-type side is formed on the exposed portion of the p-type second InN guide-layer 82.

The electrode 83 of the n-type side is coupled to an outer portion via a wire 85 and the electrode 84 of the p-type side is coupled to the outer portion via a wire 86.

The optical semiconductor device 80 is coupled to an outer source (not illustrated). When electrical current is turned on the GaN/AlN MQW core-layer 14, emission from blue violet to ultra violet generated from the GaN/AlN MQW core-layer 14 accompanying with band gap of the core-layer 14 can be obtained.

As mentioned above, the optical semiconductor device 80 in this embodiment includes the electrode 83 of the n-type side and the electrode 84 of the p-type side, respectively, on the n-type first InN guide-layer 81 and on the p-type second InN guide-layer 82 for turning electrical current to the GaN/AlN MQW core-layer 14.

According to the method mentioned above, the GaN/AlN MQW core-layer 14 can be emitted by current injection to be obtained a semiconductor emitting device.

It is explained as an example that the n-type first guide-layer 81 and the p-type second guide-layer 82 are InN, however, InₓGa_{y}Al_{(1-x-y)}N, for example, a composition of x=0.5 and y=0.5 being constituted with InGaN may be suited.

It is explained as an example that both the n-type first guide-layer 81 and the p-type second guide-layer 82 are single layers, respectively. However, InₓGa_{y}Al_{(1-x-y)}N multi-layers having different composition each other, for example, a super-lattice of InN/InGaN or InGaN/InGaAlN may be suited.

It is explained as an example that the first guide-layer 81 and the second guide-layer 82 are an n-type and a p-type. However, the first guide-layer 81 and the second guide-layer 82, respectively, may be a p-type and an n-type.

### Seventh Embodiment

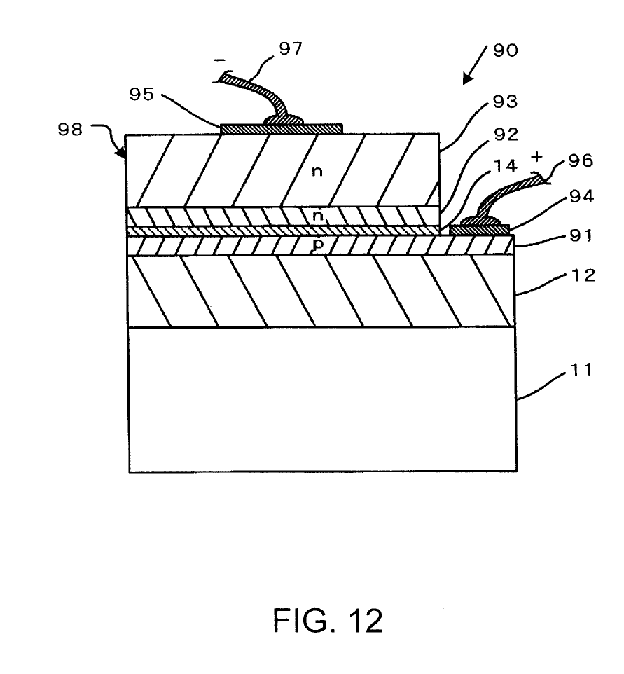

FIG. 12 is a cross-sectional schematic view showing an optical semiconductor device according to a seventh embodiment of the present invention. It is to be noted that the same reference numerals in FIG. 1 are attached to the same parts and elements in FIG. 12 as those in FIG. 1. Further, the description of the same parts and elements will be omitted and the different parts and elements will be explained.

This embodiment is different to the first embodiment in forming an electrode on the first guide-layer and the second AlN clad-layer for turning on electrical current to the GaN/AlN MQW core-layer.

As shown in FIG. 12, an optical semiconductor device 90 in this embodiment includes a p-type second InN guide-layer 91 doped with magnesium (Mg), for example, an n-type second guide-layer 92 doped with silicon (Si), for example, and an n-type second AlN clad-layer 93 doped with silicon (Si), for example.

One side of the n-type second AlN clad-layer 93, the n-type second InN guide-layer 92 and the GaN/AlN MQW core-layer 14 is removed and a portion of the p-type first InN guide-layer 91 is exposed. For example, Ni/Au as an electrode (first electrode) 94 of a p-type side is formed on the exposed portion of the p-type first InN guide-layer 91.

For example, Ti/Al as an electrode (second electrode) 95 of an n-type side is formed on the p-type second AlN clad-layer 93. Obtaining the p-type AlN with low resistance is difficult by Mg-doping, however, the n-type AlN with low resistance is easily obtained by Si-doping.

The electrode 94 of the p-type side is coupled to an outer portion via a wire 96 and the electrode 95 of the n-type side is coupled to the outer portion via a wire 97.

The optical semiconductor device 90 is coupled to an outer source (not illustrated). When electrical current is turned on the GaN/AlN MQW core-layer 14, emission from blue violet to ultra violet generated from the GaN/AlN MQW core-layer 14 accompanying with band gap of the core-layer 14 can be obtained.

As mentioned above, the optical semiconductor device 90 in this embodiment includes the electrode 94 of the p-type side and the electrode 95 of the n-type side, respectively, on the p-type first InN the guide-layer 91 and the n-type second InN guide-layer 93 for turning electrical current to the GaN/AlN MQW core-layer 14.

According to the method mentioned above, the second AlN clad-layer 93 is partially removed, however, the n-type second InN guide-layer 92 is not necessary exposed, the optical semiconductor device 90 has an advantage being easily fabricated.

As the electrode 95 of the n-type side is formed at a center portion of the n-type second AlN clad-layer 93, applied weight on the optical semiconductor device 90 is uniformed so that damage on the optical semiconductor device 90 is eliminated when a wire 97 is bonded to the electrode 95 of the n-type side.

As an optical wave guide 98 is formed as a ridge-type with stripes, a reflection film is formed on the both side walls so that the optical semiconductor device 90 can be constructed as a semiconductor laser device.

### Eighth Embodiment

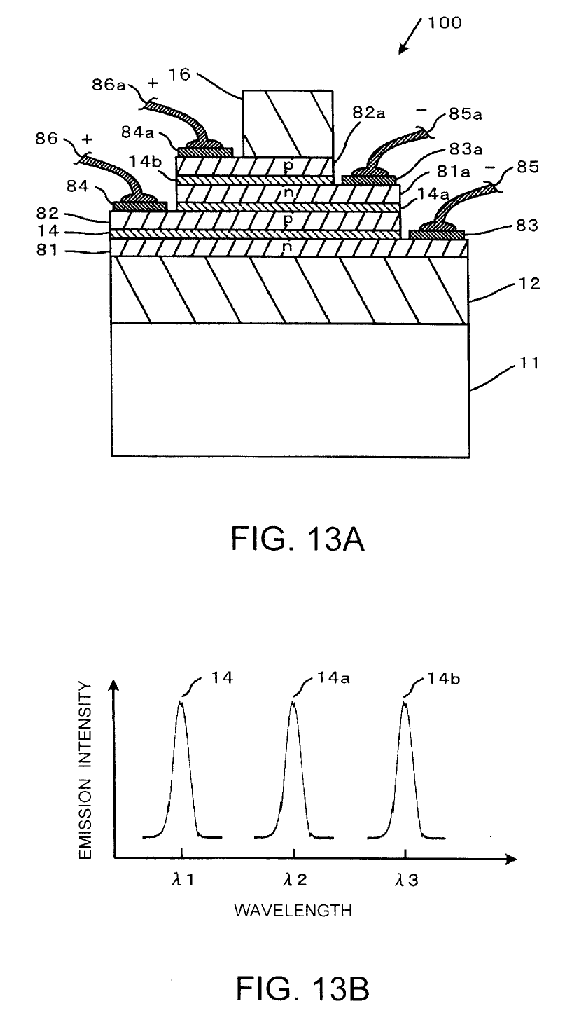

FIG. 13A is a cross-sectional schematic view showing an optical semiconductor device and FIG. 13B is a photo-emission spectrum showing characteristic of the optical semiconductor device according to an eighth embodiment of the present invention. It is to be noted that the same reference numerals in FIG. 1 are attached to the same parts and elements in FIGS. 13A and 13B as those in FIG. 1. Further, the description of the same parts and elements will be omitted and the different parts and elements will be explained.

This embodiment is different to the first embodiment in forming the InN guide-layer and the GaN/AlN MQW core-layer having different band gaps each other alternatively in order and forming an electrode at the InN guide-layer for turning on electrical current to the GaN/AlN MQW core-layer.

As shown in FIG. 13A, an optical semiconductor device 100 in this embodiment is stacked the GaN/AlN MQW core-layer 14a, the n-type first InN guide-layer 81a, the GaN/AlN MQW core-layer 14b and the p-type second InN guide-layer 82a on the p-type second InN guide-layer 82 in order.

One side from the second AlN clad-layer 16 to the GaN/AlN MQW core-layer 14b is removed and the electrode 83a of n-type side is formed on the exposed portion of the n-type first InN guide-layer 81a. The electrode 83a of the n-type side is coupled to an outer portion via wire 85a.

Another portion of the second AlN clad-layer 16 is removed and an electrode 84a is formed on the exposed portion of the p-type second InN guide-layer 82a. The electrode 84a of the p-type side is coupled to the outer portion via wire 86a.

Each of GaN/AlN MQW core-layers 14, 14a and 14b is doped with In into GaN quantum well layer in order to narrow each band gap. Band gap is narrowed with increasing In-doping.

Further, band gap of the GaN/AlN MQW core-layer can be narrowed with increasing a film thickness of a GaN quantum well layer.

As shown in FIG. 13B, when the wire 85 is coupled to a minus terminal of an outer source (not illustrated) and the wire 86 is coupled to a plus terminal of the outer source, the GaN/AlN MQW core-layer 14 is turned on to obtain emission of wavelength λ1 from the GaN/AlN MQW core-layer 14.

Similarly, when a wire 85a is coupled to a minus terminal of an outer source (not illustrated) and the wire 86 is coupled to a plus terminal of the outer source, a GaN/AlN MQW core-layer 14a is turned on to obtain emission of wavelength λ2 from the GaN/AlN MQW core-layer 14a.

Similarly, when the wire 85a is coupled to a minus terminal of an outer source (not illustrated) and a wire 86a is coupled to a plus terminal of the outer source, a GaN/AlN MQW core-layer 14b is turned on to obtain emission of wavelength λ3 from the GaN/AlN MQW core-layer 14b.

According to the method mentioned above, the optical semiconductor device 100 emitting three wavelengths of light can be obtained. Further, each of the GaN/AlN MQW core-layer 14, 14a and 14b are simultaneously turned on to be able to emit mixture light with three wavelengths.

As mentioned above, the optical semiconductor device 100 in this embodiment is alternatively formed of the InN guide-layer and the GaN/AlN MQW core-layer with different band gap to that of the InN guide-layer. The optical semiconductor device 100 is also formed of the electrode on each InN guide-layer to turn on each GaN/AlN MQW core-layer.

As a result, the optical semiconductor device 100 individually or simultaneously emits different wavelengths at the same point is obtained.

It is explained as an example that, In is doped to modulate band gap of the GaN/AlN MQW core-layer. However, adjusting a film thickness ratio between the GaN quantum well layer and the AlN barrier-layer can be also used. In this case, emitting wavelength range (Δλ=λ3−λ1) becomes small.

It is explained as an example that the electrodes 83 and 83a as the n-type side are formed at one terminal and the electrodes 84 and 84a as the p-type side are formed at another terminal. However, the electrodes 84 and 84a can be formed at the one terminal when resistance of the InN guide-layer is fully low and current spreading can be retained.

### Ninth Embodiment

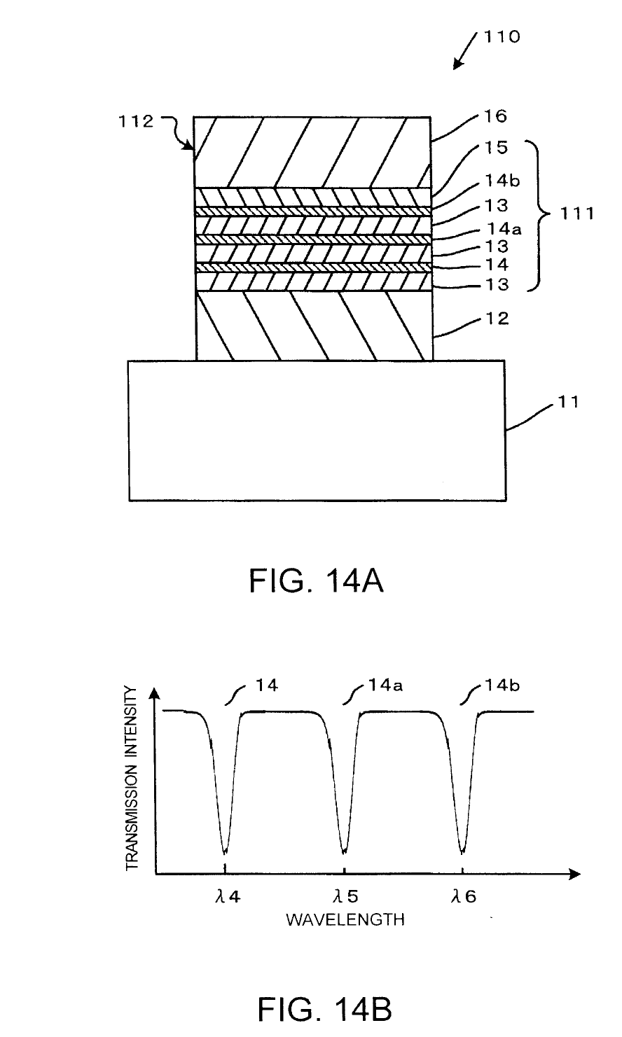

FIG. 14A is a cross-sectional schematic view showing an optical semiconductor device and FIG. 14B is a photo-absorption spectrum showing the optical semiconductor according to a ninth embodiment of the present invention. It is to be noted that the same reference numerals in FIG. 1 are attached to the same parts and elements in FIGS. 14a and 14b as those in FIG. 1. Further, the description of the same parts and elements will be omitted and the different parts and elements will be explained.

This embodiment is different to the first embodiment in alternatively forming the InN guide-layer and the GaN/AlN MQW core-layer in order, each layer having different band gap each other.

As shown in FIG. 14A, an optical semiconductor device 110 in this embodiment includes an optical wave guide 112 having a core portion 111 stacked the GaN/AlN MQW core-layers 14,14a and 14b in order, the first InN guide-layers 13 being sandwiched between each GaN/AlN MQW core-layer.

As shown in FIG. 14B, when infrared of band 1.3-1.55 μm is emitted into the optical wave guide 112, infrared of wavelength λ4, λ5 and λ6 can be absorbed corresponding to each intersubband transition in quantum well. The absorbed wavelength is longer with narrowing intersubband gap in the GaN/AlN MQW core-layer.

The intersubband gap of each GaN/AlN MQW core-layer can be modulated by changing a film thickness of the GaN quantum well layer.

The intersubband gap of GaN/AlN MQW core-layer is widened and the absorbed wavelength is shortened with decreasing the film thickness of the GaN quantum well layer.

As mentioned above, the optical semiconductor device 110 in this embodiment is alternatively formed the InN guide-layer and the GaN/AlN MQW core-layer, each layer having different band gap.

According to the method mentioned above, a multi-wavelength optical switch being monolithically formed can be obtained to absorb light with a plurality of wavelengths.

### Tenth Embodiment

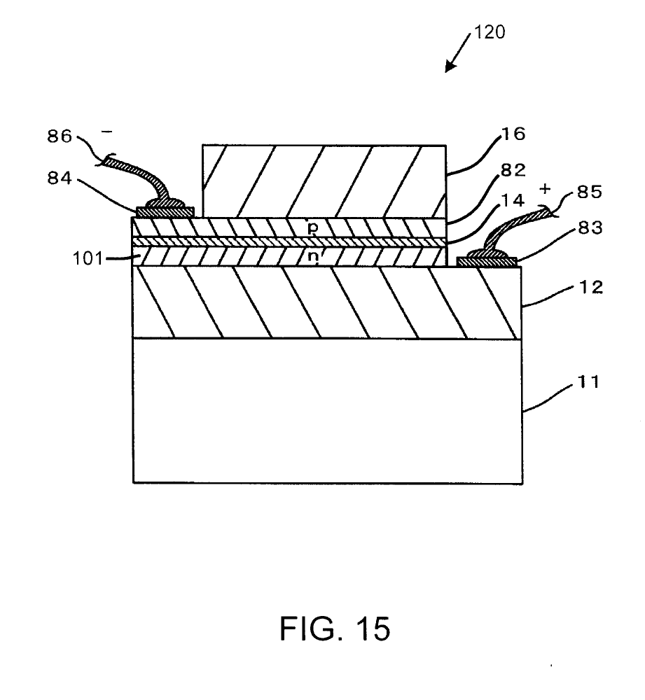

FIG. 15 is a cross-sectional schematic view showing an optical semiconductor device according to a tenth embodiment of the present invention. This embodiment is a modification of the sixth embodiment as shown in FIG. 11. It is to be noted that the same reference numerals in FIG. 1 are attached to the same parts and elements in FIG. 15 as those in FIG. 1. Further, the description of the same parts and elements will be omitted and the different parts and elements will be explained.

In the sixth embodiment, the electrodes are formed on the n-type first guide-layer 81 and the p-type second guide-layer 82 for turning on the GaN/AlN MQW core-layer 14.

On the other hand, electrodes are formed on the first AlN clad-layer 12 and the p-type second guide-layer 82 to turn on the GaN/AlN MQW core-layer 14 in this embodiment.

As shown in FIG. 15, an optical semiconductor device 120 in this embodiment includes an n-type first InN guide-layer 101 doped with Si, for example, and the p-type second InN guide-layer 82 doped with Mg, for example.

One side of the second AlN clad-layer 16, the p-type second InN guide-layer 82, the GaN/AlN MQW core-layer 14 and the n-type first InN guide-layer 101 is removed respectively and a portion of the first AlN clad-layer 12 is exposed. For example, Ti/Al as the electrode 83 of n-type side is formed on the exposed portion of the first AlN clad-layer 12.

Similarly, another side of the second AlN clad-layer 16 is removed and a portion of the p-type second InN guide-layer 82 is exposed, for example, Ni/Au as the electrode 84 of the p-type side is formed on the exposed portion of the p-type second InN guide-layer 82.

The electrode 83 of n-type side is coupled to an outer portion via the wire 85 and the electrode 84 of the p-type side is coupled to the outer portion via the wire 86.

An optical semiconductor 120 is coupled to an outer source (not illustrated). When electrical current is turned on the GaN/AlN MQW core-layer 14, emission from blue violet to ultra violet generated from the GaN/AlN MQW core-layer 14 accompanying with band gap of the core-layer 14 can be obtained.

As mentioned above, the optical semiconductor device 120 in this embodiment includes the electrode 83 of the n-type side and the electrode 84 of the p-type side on the second AlN clad-layer 16 and the p-type second InN guide-layer 82 respectively, to turn on the GaN/AlN MQW core-layer 14.

According to the method mentioned above, the GaN/AlN MQW core-layer 14 can be emitted by current injection to obtain the semiconductor emitting device.

Further, as compared to the sixth embodiment, the structure is obtained by etching from the second AlN clad-layer 16 to the n-type the first InN guide-layer 101, therefore, fabricating processes become easily. Further, doping concentration in the n-type first InN guide-layer 101 can be decreased or the n-type first InN guide-layer 101 can be undoped. In this case, performance of the device is the same as the sixth embodiment.

It is explained as an example that the n-type first guide-layer 81 and the p-type second guide-layer 82 are constituted with InN, however, InₓGa_{y}Al_{(1-x-y)}N, for example, having a composition x=0.5, y=0.5 of InGaN may be suited.

It is explained as an example that the n-type first guide-layer 81 and the p-type second guide-layer 82 are single layers, respectively. However, InₓGa_{y}Al_{(1-x-y)}N multiple-layer with different compositions, for example, a supper lattice of InN/InGaN or InGaN/InGaAlN may be suited.

It is explained as an example that the first guide-layer 81 and the second guide-layer 82 are an n-type and a p-type, respectively. However, the first guide-layer 81 and the second guide-layer 82 may be a p-type and an n-type, respectively.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, the photo-emitting devices in the embodiments are demonstrated as optical devices. However, another optical device such as a photo-absorbing device can be also applied.

What is claimed is:

1. An optical semiconductor device, comprising;
a first AlN clad-layer,
a first nitride semiconductor guide-layer formed on the first AlN clad-layer, refractive index of the first nitride semiconductor guide-layer being larger than refractive index of the first AlN clad-layer,
a nitride semiconductor core-layer formed on the first nitride semiconductor guide-layer, refractive index of the nitride semiconductor core-layer being larger than refractive index of the first AlN clad-layer and smaller than refractive index of the first nitride semiconductor guide-layer,
a second nitride semiconductor guide-layer formed on the nitride semiconductor core-layer, refractive index of the second nitride semiconductor guide-layer being larger than refractive index of the nitride semiconductor core-layer,
a second AlN clad-layer formed on the second nitride semiconductor guide-layer.

2. The optical semiconductor device according to claim 1, further comprising;
a plurality of the first nitride semiconductor guide-layers and a plurality of the nitride semiconductor core-layers alternatively stacked on the first AlN clad-layer in order.

3. The optical semiconductor device according to claim 1, wherein
the nitride semiconductor core-layer is constituted with GaN/AlN.

4. The optical semiconductor device according to claim 2, wherein
the plurality of the nitride semiconductor core-layer are constituted with GaN/AlN, each of the nitride semiconductors has a different band gap each other.

5. The optical semiconductor device according to claim 4, wherein
the band gap is controlled by a film thickness of the nitride semiconductor core-layer.

6. The optical semiconductor device according to claim 1, wherein
the first nitride semiconductor guide-layer and the second nitride semiconductor guide-layer are constituted with one of InN or InGaAlN, respectively.

7. The optical semiconductor device according to claim 6 wherein,
InGaAlN has a composition of InₓGa_{y}Al_{(1-x-y)}N, x being more than 0.5, y being less than 0.5 and 1−x−y being less than 1 as the composition.

8. The optical semiconductor device according to claim 6, wherein
the first nitride semiconductor guide-layer and the second nitride semiconductor guide-layer are respectively constituted with InGaAlN stacked-layers, each of the InGaAlN stacked-layers having a different band gap each other.

9. The optical semiconductor device according to claim 8, wherein
Each of the InGaAlN stacked-layers has a composition of InₓGa_{y}Al_{(1-x-y)}N, x being more than 0.5, y being less than 0.5 and 1−x−y being less than 1 as the composition.

10. The optical semiconductor device according to claim 1, further comprising;
a first electrode formed on a portion of the first nitride semiconductor guide-layer,
a second electrode formed on a portion of the second nitride semiconductor guide-layer, the second nitride semiconductor guide-layer having an opposite conductive-type against a conductive-type of the first nitride semiconductor guide-layer.

11. The optical semiconductor device according to claim 1, wherein
the first electrode is formed on the portion of the first nitride semiconductor guide-layer and the second electrode formed on a portion of the second AlN clad-layer.

12. The optical semiconductor device according to claim 1, wherein
the first electrode is formed on a portion of the first AlN clad-layer and the second electrode formed on the portion of the second nitride semiconductor guide-layer.

13. The optical semiconductor device according to claim 2, wherein
the first nitride semiconductor guide-layer having a first end portion having the first electrode thereon and the first nitride semiconductor guide-layer having a second end portion having the second electrode thereon are alternatively stacked in the plurality of the first nitride semiconductor guide-layers.

14. A method for fabricating an optical semiconductor device, comprising;
forming a first AlN clad-layer over a substrate;
forming a first nitride semiconductor guide-layer on the first AlN clad-layer, refractive index of the first nitride semiconductor guide-layer being larger than refractive index of the first AlN clad-layer;
forming a nitride semiconductor core-layer on the first nitride semiconductor guide-layer, refractive index of the nitride semiconductor core-layer being larger than refractive index of the first AlN clad-layer being smaller than refractive index of the first nitride semiconductor guide-layer;
forming a second nitride semiconductor guide-layer on the nitride semiconductor core-layer, refractive index of the second nitride semiconductor guide-layer being larger than refractive index of the nitride semiconductor core-layer;
forming a second AlN clad-layer on the second nitride semiconductor guide-layer.

15. The method for fabricating the optical semiconductor device according to claim 14, further comprising;
forming a buffer layer on the substrate before forming the first AlN clad-layer.

16. The method for fabricating the optical semiconductor device according to claim 14, further comprising;
alternatively stacking a plurality of the first nitride semiconductor guide-layers and a plurality of the nitride semiconductor core-layer in order on the first AlN clad-layer.

17. The method for fabricating the optical semiconductor device according to claim 14, wherein
forming the first nitride semiconductor guide-layer and the second nitride semiconductor guide-layer as stacked-layers constituted with InGaAlN, each of the first nitride semiconductor guide-layer and the second nitride semiconductor guide-layer having a different composition each other.

18. The method for fabricating the optical semiconductor device according to claim 14, further comprising;
removing a first end portion and a second end portion of the second AlN clad-layer so as to expose a first end portion and a second end portion of the second nitride semiconductor guide-layer;
removing a first end portion of the second nitride semiconductor guide-layer and a first end portion of the nitride semiconductor core-layer so as to expose a first end portion of the first nitride semiconductor guide-layer;
forming a first electrode on the first end portion of the first nitride semiconductor guide-layer;
forming a second electrode on the second end portion of the second nitride semiconductor guide-layer.

19. The method for fabricating the optical semiconductor device according to claim 14, further comprising;
removing the first end portion of the second AlN clad-layer, the first end portion of the second nitride semiconductor guide-layer and the first end portion of the nitride semiconductor core-layer so as to expose the first end portion of the first nitride semiconductor guide-layer;
forming the first electrode on the first end portion of the first nitride semiconductor guide-layer;
forming the second electrode on the second AlN clad-layer.

20. The method for fabricating the optical semiconductor according to claim 14, further comprising;
removing the first end portion and the second end portion of the second AlN clad-layer so as to expose the first end portion and the second end portion of the second nitride semiconductor guide-layer;
removing the first end portion of the second nitride semiconductor guide-layer and the nitride semiconductor core-layer, and a first end portion of the first nitride semiconductor guide-layer so as to expose a first end portion of the first AlN clad-layer;
forming the first electrode on the first end portion of the first AlN clad-layer;
forming the second electrode on the second end portion of the second nitride semiconductor guide-layer.
